(19) United States
(12) Patent Application Publication
(10) Pub. No.: US 2017/0287799 A1
(43) Pub. Date: Oct. 5, 2017

(54) REMOVABLE IC PACKAGE STIFFENER

(71) Applicants: Steven A. Klein, Chandler, AZ (US); Aditya S. Vaidya, Tempe, AZ (US); Vijay Krishnan Subramanian, Chandler, AZ (US); Santosh Sankarasubramanian, Chandler, AZ (US); Pramod Malatkar, Chandler, AZ (US); Suriyakala Suriya Ramalingam, Chandler, AZ (US); Ashish Dhall, Chandler, AZ (US)

(72) Inventors: Steven A. Klein, Chandler, AZ (US); Aditya S. Vaidya, Tempe, AZ (US); Vijay Krishnan Subramanian, Chandler, AZ (US); Santosh Sankarasubramanian, Chandler, AZ (US); Pramod Malatkar, Chandler, AZ (US); Suriyakala Suriya Ramalingam, Chandler, AZ (US); Ashish Dhall, Chandler, AZ (US)

(21) Appl. No.: 15/088,998

(22) Filed: Apr. 1, 2016

(51) Int. Cl. H01L 23/16; H01L 21/54

(52) U.S. Cl. CPC H01L 23/16; H01L 21/54

(57) ABSTRACT

A stiffener, an IC package and methods of fabrication of an IC package including a removable stiffener are shown. A removable stiffener for use with an integrated circuit (IC), including a plurality of adhesive portions disposed between a surface of the stiffener and a surface of a substrate of the IC is shown. Such a removable stiffener including at least one removal tab is shown. An IC package including a removable stiffener including a plurality of adhesive portions disposed between a surface of the stiffener and a surface of a substrate of the IC is shown. Methods of fabrication of an IC package including a removable stiffener are shown.

### TECHNICAL FIELD

Embodiments described herein generally relate to microelectronic structures, and, more particularly to the fabrication of integrated circuit packages and electronic assemblies.

### BACKGROUND

Fabrication of an integrated circuit (IC) package, is a multi-step process, which includes patterning, deposition, etching, and metallization. In final processing, a resulting IC die can be separated and packaged. A first plurality of solder bump structures (e.g., solder bumps, balls, pads, pillar bumps (e.g., copper pillar bumps), etc.) of a generally uniform size can be positioned between the die and a substrate, and the die and substrate can be heated to similar temperatures. The die can then be lowered onto the substrate, in order to mechanically and electrically couple the die to the substrate. Heat can be applied via a solder reflow process to re-melt the solder bumps and attach the die to the substrate. Attachment of the die to the substrate (i.e., primary substrate), to form the IC package, is referred to as a “first level interconnection” (FLI). The IC package may further be underfilled with a non-conductive adhesive, or over-molded, to strengthen the mechanical connection between the die and the substrate. One or more such IC packages can be physically and electrically coupled to a secondary substrate, such as a printed circuit board (PCB) or a motherboard. Attachment of the IC package(s) directly to the secondary substrate, such as by soldering, is referred to as a “second level interconnection” (SLI).

Surface mount technology (SMT) is a widely known technique that can be used in forming SLIs, for example. SMT, using a ball-grid-array (BGA), can be used to form a SLI by coupling one or more IC packages to a secondary substrate, such as a PCB or motherboard. Solder bumps, for example, can be employed between lands on the IC package and corresponding lands on the PCB, thereby forming interconnections.

### BRIEF DESCRIPTION OF THE DRAWINGS

FIG. 1 shows a cross-section of an example of an IC package.

FIG. 2 shows a top view of an example of an IC package including an example of a stiffener (in ghost view).

FIG. 3 shows a top view of an example of a stiffener.

FIG. 4 shows a side view of the stiffener of FIG. 4.

FIG. 5 shows a top view of an example of an IC package including an example of a stiffener.

FIG. 6 shows a cross-section of the IC package and the stiffener of FIG. 5 taken at line 6-6 (FIG. 5).

FIG. 7 shows a block diagram of an example of an electronic system.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

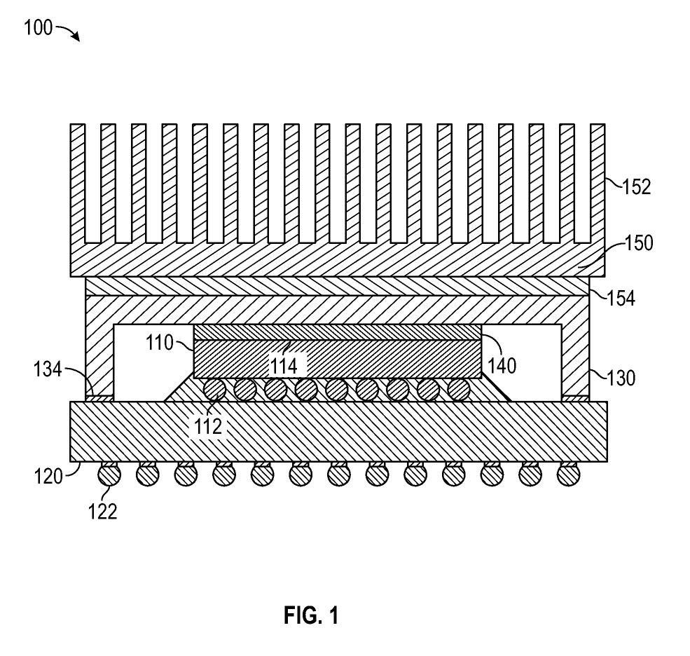

FIG. 1 shows a cross-section of an example of an IC package 100. IC package 100 includes a die 110 mounted in flip-chip orientation with its active side facing downward to couple with an upper surface of a substrate 120, through a number of first level interconnections 112, such as solder bump structures, solder balls or solder bumps. A BGA of such first level interconnections 112 can be used to form IC package 100, for example. Also, in FIG. 1, the substrate 120 shows a number of second level interconnections 122, such as solder balls, on its opposite surface for mating with an additional packaging structure, such as a PCB (not shown).

Die 110 generates its heat from internal structure, including wiring traces, located near its active side; however, a significant portion of the heat is dissipated through its back side 114. Heat that is concentrated within the die 110 is dissipated to a large surface that is in contact with the die 110 in the form of an integrated heat spreader 130. A thermal interface material 140 can be provided between the die 110 and integrated heat spreader 130. In one embodiment, to further dissipate heat from the integrated heat spreader 130, a heat sink 150 optionally having fins 152 can be coupled to the integrated heat spreader 130.

Manufacturing of an IC package, using SMT for example, can involve multiple thermal cycling (or processing) steps. For instance, a substrate may be heated to add solder balls (e.g., flip-chip or controlled collapse chip connection (C4) solder balls) to a substrate. The substrate may again be heated one or more times for die placement and solder reflow. Another thermal cycle may be added if epoxy, for example, is used in the assembly process as an underfill material. An underfilling process, such as capillary-flow underfilling, relies upon capillary pressure of the underfill material, to flow between the substrate and the die. Yet another thermal cycle may be used to incorporate the IC package into an electronic assembly.

The multiple thermal cycles can lead to warpage of components of a resulting IC package or electronic assembly. Warpage refers to a bending or twist or general lack of flatness in an overall IC package, for example, including particularly the plane formed by solder joint locations. Such warpage is caused by a difference in coefficients of thermal expansion (CTE) between one part or component and another. The problem of IC package warpage can be exacerbated in larger packages due to the larger size, and can also be exacerbated when soldering temperatures become higher and IC packages become thinner Recently, the use of lead-free solders has become more prevalent on certain product types. This lead-free solder generally requires a higher soldering temperature than prior solders.

Warpage can pose a problem in forming solder joints, or interconnections, in IC packages. A lack of flatness can occur where the entire package warps so that it is curved or bent or otherwise non-flat. Lack of flatness in an IC package can cause various problems such as poor soldered joints between the IC package and a substrate, poor or no contact at the solder joints, undesirably pillowed joints, or intermittent contact at the solder joints. Such warpage can cause an IC package or an electronic assembly to fail.

The inventors have recognized that it can be beneficial to reduce warpage of an IC package, or other components, during manufacture or assembly of electronic assemblies. Inhibiting warpage during the manufacture or assembly of electronic assemblies can increase yield and thereby increase profits.

One solution to the problem of IC package warpage has been the incorporation of a flat stiffener plate on top of the IC to maintain planarity of the components. The stiffener plate takes the form essentially of a completely flat, entirely planar item generally having a constant thickness, and can be a simple rectangle having approximately its perimeter be the size of the IC package perimeter when viewed from the top, although other shapes are contemplated. A central region of the stiffener plate may be cut out (include an aperture) to accommodate for one or more components, such as a die or dies, for example.

The stiffener plate, or “stiffener,” can be attached to a substrate by adhesive, which can be a thermally set adhesive dispensed in liquid, semi-liquid or preformed formats. A bottom surface of the stiffener that attaches to the substrate is covered by adhesive. The inventors have recognized a problem encountered when applying adhesive to the bottom surface of the stiffener in order to attach the stiffener, which is the tendency of the adhesive to “bleed” and spread onto wire bond surfaces, such as wire bond pads or other noble metal surfaces, such as ground rings or voltage rings, and adhere thereto. This “adhesive bleed” results in unsatisfactory electrical contacts and can, thus, contribute to an unsatisfactory IC package. In particular, there are high risk areas where the adhesive is located closer to more critical components, and adhesive bleed in that area can more negatively affect the IC package. The present subject matter can help provide a solution to the problem of adhesive bleed by limiting adhesive application to at or near the four corners of the stiffener only, for example. An additional benefit to using a plurality of adhesive portions (i.e., patches, spots or drops) only at the four corners, for example, is that less adhesive is necessary, which results in a cost savings.

The inventors have recognized another problem with using stiffeners in the fabrication of IC packages and electronic assemblies in order to prevent warpage. The problem is that stiffeners add to the cost of manufacture of electronic assemblies, and are not removable or reusable. The present subject matter can help provide a solution to the problem by fabricating the stiffeners or attaching them in such a way that the stiffeners are removable after SMT and reusable, thus resulting in cost savings. Using less adhesive on removable stiffeners can make the stiffeners easier to remove, clean and reuse.

Many embodiments relate to a stiffener that can be attached to an IC package. As used throughout this document, the terms IC (integrated circuit) and IC packaging are used interchangeably to make reference to the overall component assembly, which is also commonly referred to as the IC package. IC packaging can take on the form of Area Array style packaging, which itself can include various subtypes, such as for example Column Grid Arrays (CCGA), Pin Grid Arrays (PGA), and Ball Grid Arrays (BGA). The term IC assembly is used herein to refer to an IC or IC package that has a stiffener incorporated therein or mounted thereto, although the terms IC and IC package can also refer to an item including an IC with a stiffener.

When referring herein to a plane, the reference includes the concept of a flat stiffener, which actually has a top and bottom flat surface and some thickness, with the top and bottom flat surfaces technically lying along parallel planes. Planar herein includes the concept of a stiffener being planar although it has such a thickness.

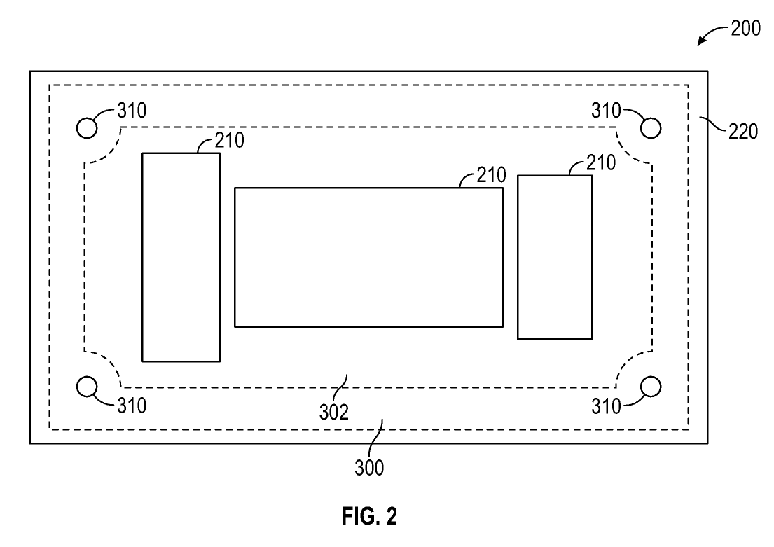

FIG. 2 shows a top view of an example of an IC package 200 including a stiffener 300 (in ghost view). IC package 200 can include a plurality of dies 210, for example, attached to a substrate 220. Due to flexibility of the substrate 220, or possible warpage during thermal processing, the stiffener 300 can be attached to the substrate 220 at or near its perimeter.

Stiffener 300 can include a flat planar portion and can form a rectangular frame, although other shapes are also contemplated. The stiffener can include a central aperture 302 or apertures in any locations as necessary to accommodate components of an IC package, for example.

Stiffener 300 can be attached to a mounting location on the substrate 220 by a plurality of adhesive portions 310, applied between the stiffener 300 and the substrate 200, for example. The plurality of adhesive portions 310 can be located at or near the corners of the substrate 200 (as shown), for example, or can be at any other locations between the stiffener 300 and the substrate 220. Limiting the adhesive to the plurality of adhesive portions 310 at or near the corners of the stiffener 300 can avoid adhesive bleed onto interconnections between the die 210 and the substrate 220, for example In addition, limiting the amount of adhesive to a plurality of adhesive portions 310, for example, can also allow the stiffener 300 to be subsequently removed and reused.

The plurality of adhesive portions used, such as 310 in FIG. 2, can be dispensed at room temperature at or near corners of a substrate of an IC package, prior to thermal processing. The plurality of adhesive portions can be pre-dispensed onto one of the components, or can be applied at any time prior to thermal processing. The plurality of adhesive portions can be in any shape, such as circular-shaped, L-shaped, rectangular-shaped, etc. Although the locations of the plurality of adhesive portions is shown herein as being at or near the corners, the plurality of adhesive portions can alternatively or additionally be applied at other locations for warpage reduction or stiffener attachment. The plurality of adhesive portions can also be applied such that, upon thermal processing, the plurality of adhesive portions do not interfere with the interconnections between components of an electronic assembly.

A liquid adhesive can be used, such as to form the plurality of adhesive portions 310 at the corners, or other locations, of the stiffener 300. The plurality of adhesive portions 310 can be drops, spots, patches, or interrupted strips of a suitable adhesive, for example. Alternatively, a film adhesive (not shown) can be used. A cover tape can be applied to the film adhesive on the stiffener, for example, which can be removed just prior to attaching the stiffener to the substrate, for example. Other types of suitable adhesive portions are also contemplated.

One example of an adhesive can be an epoxy, or any polyepoxide. However, the adhesive can also be any other suitable adhesive, such as any acrylate, any polyimide, or any polyamide. The adhesive can also be a thermo-plastic adhesive, such as ethylene vinyl acetate or any polyurethane compound, for example. Generally, adhesives having a high modulus-high adhesion and a high glass transition temperature, such as 180 to 200 degrees Celsius, for example, are preferred, such that modulus of the adhesive stays high for a significant portion of thermal processing.

A debonding adhesive can also be used to attach the stiffener 300 to the substrate 220. A debonding adhesive is an adhesive that can be debonded using one of several trigger methods, such as heat, electricity, chemical application, light, or magnetic flux, etc., for example. Some examples of debonding adhesives that can be used include, but are not limited to, thermal release films, polypropylene carbonate, ELECTRELEASE™, SINUATE™, water soluble adhesives, UV release films, etc. Other suitable debonding adhesives can also be used.

If a debonding adhesive is used, the adhesive can be applied between the stiffener and substrate at a plurality of locations, but preferably to avoid adhesive bleed onto electrical interconnections. After SMT, and after a debonding method is applied to debond the adhesive located at a plurality of locations between the stiffener and the substrate, for example, the stiffener can then be removed and reused.

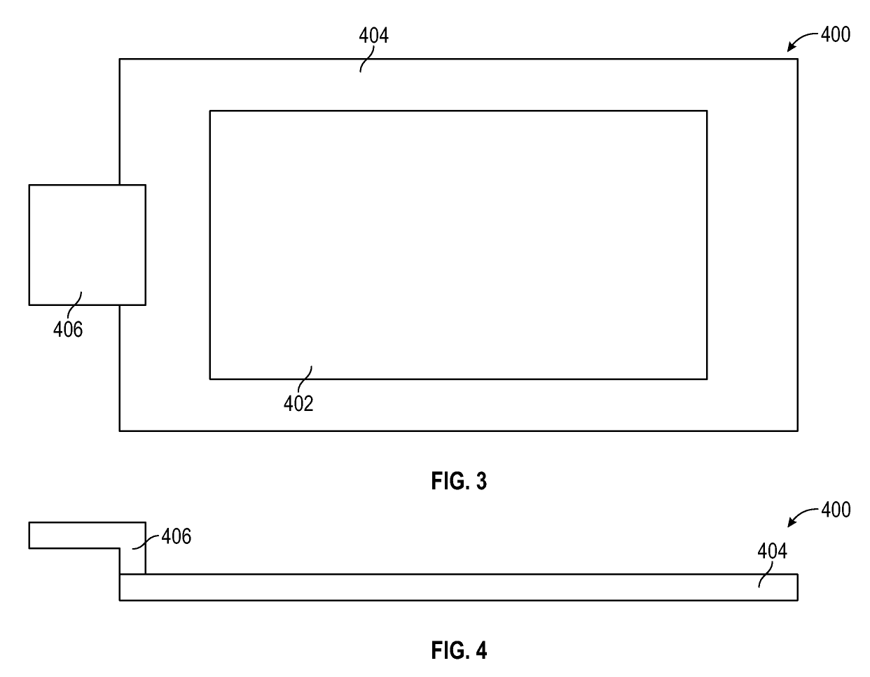

FIGS. 3 and 4 show a top view and a side view, respectively, of another example of a stiffener 400. Stiffener 400 can be attached to a substrate by a plurality of adhesive portions (not shown) using any suitable technique as described herein. Stiffener 400 includes a central aperture 402 (or can include apertures) to accommodate other components that may be attached to the substrate. Stiffener 400 includes a frame portion 404 and a removal tab portion 406. Removal tab 406 can be attached to frame portion 404 at an end of stiffener 400 or at another location along frame portion 404, or removal tab 406 can be formed integrally as part of the stiffener 400. The removal tab 406 can provide a handle or a location where stiffener 400 can be held in order to remove the stiffener 400 from a substrate, such as by using a pulling or pushing force.

The embodiment shown in FIGS. 3 and 4, including the removal tab 406, can be combined with the embodiment shown in FIG. 2, for example. Thus, a plurality of adhesive portions can be used to attach the stiffener 400 to an IC package. Limiting the amount of adhesive to a plurality of adhesive portions can allow the stiffener 400 with removal tab 406 to be more easily removed from an IC package and reused.

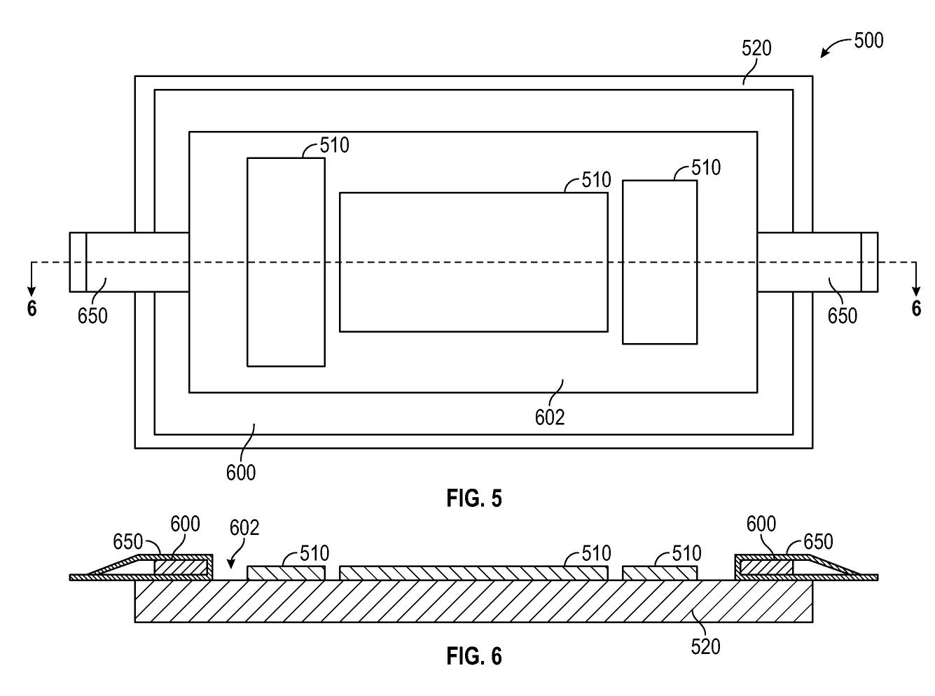

FIGS. 5 and 6 shows a top view and a cross-section, respectively, of another example of an IC package 500 with an attached stiffener 600. IC package 500 can include a plurality of dies 510 and a substrate 520, for example, although other components are also contemplated. Due to flexibility of the substrate 520, or possible warpage during thermal processing, the stiffener 600 can be attached to the substrate 520 at or near its perimeter. Stiffener 600 can include a flat planar portion and can form a rectangular frame, although other shapes are also contemplated. The stiffener 600 can include a central aperture 602 or apertures in any locations as necessary to accommodate components of IC package 500, for example.

Stiffener 600 can be attached to a mounting location on the substrate 520 by a plurality of adhesive portions (not visible) applied between the stiffener 600 and the substrate 500 for example, or by any other suitable method of attachment described herein or otherwise. Limiting the amount of adhesive to a plurality of adhesive portions can allow the stiffener 600 to be more easily removed and reused.

In order to remove the stiffener 600, after SMT, the stiffener 600 can include at least one removal tab portion 650 (two are shown). Removal tabs 650 can be wrapped around stiffener 600 and can be held in place under the stiffener 600 by the plurality of adhesive portions (not shown) that are coupling the stiffener 600 and substrate 520. The removal tabs 650 can be used to remove the stiffener 600 by grasping and exerting a pulling force on the removal tab 650, for example. There are two removal tabs 650 shown, although other numbers are contemplated. Removal tabs 650 can be made of a piece of material that is wrapped around the stiffener 600 at or near the end, or other locations. As shown, the removal tabs 650 can adhere to themselves once wrapped around the stiffener 600. Other configurations of removal tabs are contemplated, such that the removal tab is able to provide a component that can be held in order to exert a pushing or pulling force on the removal tab resulting in removal of the stiffener from the IC package, for example

One example of a material that can be used for removal tabs, such as 650, is a piece of heat resistant tape, such as KAPTON® tape. KAPTON® tape is resistant to high temperatures, which makes it a good material for the removal tabs, which have to undergo thermal processing with other components of an electronic assembly. Other materials may be used to form the removal tabs, however. Other configurations of the removal tabs are also contemplated. For example, such removal tabs may be adhered to the stiffener, for example, and not wrapped around the stiffener.

Stiffeners 300, 400, 600 can be made of any suitable material. Some examples of stiffener material include metals, plastics, ceramics or high temperature versions of such materials including high temperature plastics.

Substrates 220, 520 can be any type of substrate capable of being used for packaging ICs or other components included in an electronic assembly. Examples of such substrates include, without limitation, dielectric carriers (e.g., ceramics, glass), semiconductor wafers, PCBs, interposers, patches, and the like.

Dies 210, 510 can be any type of electronic circuit capable of being packaged. Examples of such dies include, without limitation, a central processing unit (CPU) die, a system-on-chip (SoC) die, a microcontroller die, a microprocessor die, a graphics processor die, a digital signal processor die, a volatile member die (e.g., dynamic random-access memory (DRAM die, DRAM cubes)), a non-volatile memory die (e.g., flash member, magneto-resistive RAM), and the like. Dies 210, 510 may be a custom circuit or any application-specific integrated circuit, such as a communications circuit for use in wireless devices such as cellular telephones, pagers, portable computers, two-way radios, and similar electronic systems.

Other embodiments pertain to a method of fabricating electronic assemblies, or components thereof, in which one or more of the following can result: 1) warpage can be reduced, inhibited or prevented; 2) less adhesive can be used; and, 3) stiffeners can be removed and reused. The methods described herein can be used, for example, during SMT. However, the embodiments contemplate that the described methods can be used in other processes of fabricating an electronic assembly.

An embodiment is a method of fabrication of an IC package including a removable stiffener. The method can include: providing an IC package comprising at least one die and a substrate having a surface, wherein the at least one die is attached to the surface of the substrate; providing a stiffener comprising a planar portion having a first surface and a second surface; and, attaching the second surface of the stiffener to the surface of the substrate using a plurality of adhesive portions disposed between the second surface of planar portion of the stiffener and the surface of the substrate. As discussed herein with regard to the stiffener, the plurality of adhesive portions can be located at one or more corners of the second surface of planar portion of the stiffener. The stiffener can include one or more removal tabs connected to the planar portion or formed integrally with the stiffener, in order to remove the stiffener from the IC package after thermal processing, as discussed herein. The adhesive can be a debonding adhesive, as discussed herein. The stiffener can be removed from the IC package after thermal processing is complete. The stiffener can then be cleaned, if necessary, and reused. It is also possible for the stiffener to stay attached to the IC package until after the IC package has been attached to a secondary substrate. The stiffener can then be removed and reused.

Other embodiments of the present subject matter include methods of fabricating other components of electronic assemblies or devices. The removable stiffener and the application of a plurality of adhesive portions to the stiffener, both described herein, can be used in fabricating any electronic assembly or device in which a stiffener can prove useful to reduce or prevent warp age.

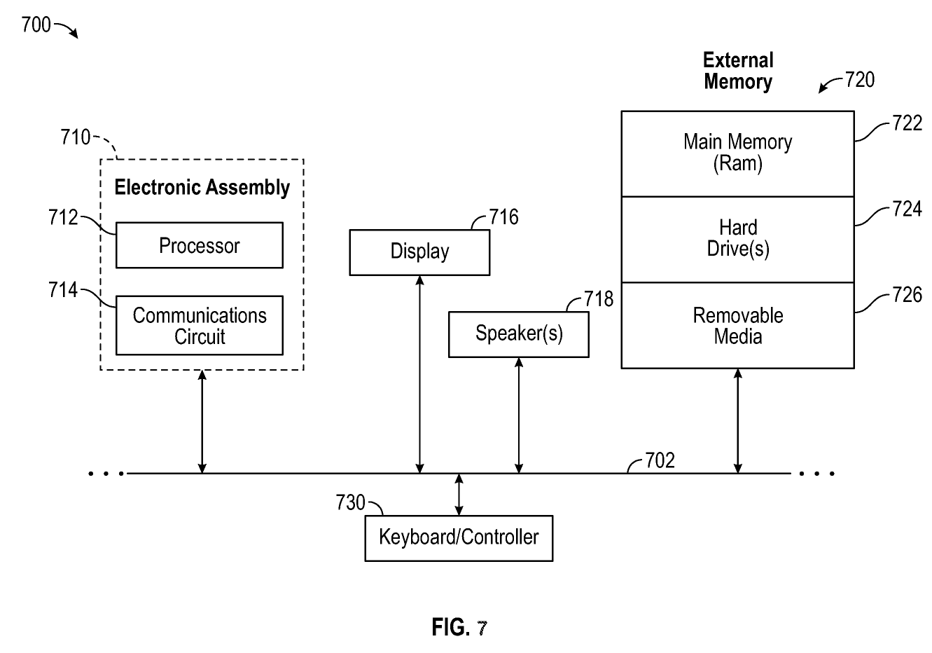

An example of an electronic device using electronic or semiconductor chip assemblies as described in the present disclosure is included to show an example of a higher level device application incorporating the embodiments described above. FIG. 7 is a block diagram of an example of an electronic device 700 incorporating a removable stiffener and/or method in accordance with at least one embodiment. Electronic device 700 is merely one example of an electronic system in which embodiments can be used. Examples of electronic devices 700 include, but are not limited to personal computers, tablet computers, mobile telephones, game devices, MP3 or other digital music players, etc. In this example, electronic device 700 comprises a data processing system that includes a system bus 702 to couple the various components of the system. System bus 702 provides communications links among the various components of the electronic device 700 and can be implemented as a single bus, as a combination of busses, or in any other suitable manner

An electronic assembly 710 is coupled to system bus 702. The electronic assembly 710 can include any circuit or combination of circuits. In one embodiment, the electronic assembly 710 includes a processor 712 which can be of any type. As used herein, “processor” means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), multiple core processor, or any other type of processor or processing circuit.

Other types of circuits that can be included in electronic assembly 710 are a custom circuit, an application-specific integrated circuit (ASIC), or the like, such as, for example, one or more circuits (such as a communications circuit 714) for use in wireless devices like mobile telephones, personal data assistants, portable computers, two-way radios, and similar electronic systems. The IC can perform any other type of function.

The electronic device 700 can also include an external memory 720, which in turn can include one or more memory elements suitable to the particular application, such as a main memory 722 in the form of random access memory (RAM), one or more hard drives 724, and/or one or more drives that handle removable media 726 such as compact disks (CD), flash memory cards, digital video disk (DVD), and the like.

The electronic device 700 can also include a display device 716, one or more speakers 718, and a keyboard and/or controller 730, which can include a mouse, trackball, touch screen, voice-recognition device, or any other device that permits a system user to input information into and receive information from the electronic device 700.

To better illustrate the methods and apparatuses disclosed herein, a non-limiting list of embodiments is provided here:

Example 1 includes a stiffener for use with an IC including a substrate having a surface, the stiffener comprising: a planar portion having a first surface and a second surface; and a plurality of adhesive portions disposed between the second surface of planar portion of the stiffener and the surface of the substrate.

Example 2 includes a stiffener of example 1, wherein the plurality of adhesive portions are located at or near one or more corners of the second surface of the planar portion of the stiffener.

Example 3 includes a stiffener of any one of examples 1-2, wherein the planar portion comprises a rectangular frame including at least one aperture.

Example 4 includes a stiffener of any one of examples 1-3, further comprising at least one removal tab.

Example 5 includes a stiffener of example 4, wherein the at least one removal tab comprises a heat resistant tape.

Example 6 includes a stiffener of example 4, wherein the at least one removal tab comprises a handle.

Example 7 includes a stiffener of any one of examples 1-6, wherein the adhesive is a debonding adhesive.

Example 8 includes an IC package, including: an IC, including at least one die and a substrate having a surface, wherein the at least one die is attached to the surface of the substrate; and, a stiffener attached to the IC, including a planar portion having a first surface and a second surface, and a plurality of adhesive portions disposed between the second surface of planar portion of the stiffener and the surface of the substrate.

Example 9 includes an IC package of example 8, wherein the plurality of adhesive portions are located at or near one or more corners of the second surface of the planar portion of the stiffener.

Example 10 includes an IC package of any one of example 8-9, wherein the planar portion comprises a rectangular frame including at least one aperture.

Example 11 includes an IC package of any one of examples 8-10, wherein the planar portion comprises a perimeter frame attached at or near a perimeter of the surface of the substrate, the frame arranged apart from the at least one die on the surface of the substrate.

Example 12 includes an IC package of any one of examples 8-11, wherein the stiffener further comprises at least one removal tab.

Example 13 includes an IC package of example 12, wherein the at least one removal tab comprises a handle.

Example 14 includes an IC package of example 12, wherein the at least one removal tab comprises a heat resistant tape.

Example 15 includes an IC package of any one of examples 8-14, wherein the adhesive is a debonding adhesive.

Example 16 includes a method of fabrication of an IC package including a removable stiffener, the method including: providing an IC package comprising at least one die and a substrate having a surface; providing a stiffener comprising a planar portion having a first surface and a second surface; and attaching the second surface of the stiffener to the surface of the substrate using a plurality of adhesive portions disposed between the second surface of planar portion of the stiffener and the surface of the substrate.

Example 17 includes a method of example 16, further comprising applying the plurality of adhesive portions at or near one or more corners of the second surface of the planar portion of the stiffener.

Example 18 includes a method of any one of examples 16-17, wherein the stiffener further comprises at least one removal tab.

Example 19 includes a method of any one of examples 16-18, further comprising attaching a removal tab to the stiffener.

Example 20 includes a method of any one of examples 16-19, further comprising removing the stiffener from the substrate after thermally processing the IC package.

These and other examples are intended to provide non-limiting examples of the present subject matter—it is not intended to provide an exclusive or exhaustive explanation. The Description of Embodiments is included to provide further information about the present methods and apparatuses.

The above Description of Embodiments includes references to the accompanying drawings, which form a part of the Description of Embodiments. The drawings show, by way of illustration, specific embodiments that can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

For expository purposes, the term “horizontal” as used herein is defined as a plane parallel to the plane or surface, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures.

The term “on” means that there is direct contact between elements. The term “directly on” means that there is direct contact between one element and another element without an intervening element.

The above Description of Embodiments is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Description of Embodiments, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Description of Embodiments, with each claim standing on its own as a separate embodiment, and it is contemplated that such embodiments can be combined with each other in various combinations or permutations. The scope of the subject matter should be determined with reference to the appended claims, along with the full scope of equivalents to which such claims are entitled.

1. A stiffener for use with an integrated circuit (IC) including a substrate having a surface, the stiffener comprising:
a planar portion having a first surface and a second surface; and
a plurality of adhesive portions disposed between the second surface of planar portion of the stiffener and the surface of the substrate.

2. The stiffener of claim 1, wherein the plurality of adhesive portions are located at or near one or more corners of the second surface of the planar portion of the stiffener.

3. The stiffener of claim 1, wherein the planar portion comprises a rectangular frame including at least one aperture.

4. The stiffener of claim 1, further comprising at least one removal tab.

5. The stiffener of claim 4, wherein the at least one removal tab comprises a heat resistant tape.

6. The stiffener of claim 4, wherein the at least one removal tab comprises a handle.

7. The stiffener of claim 1, wherein the adhesive is a debonding adhesive.

8. An integrated circuit (IC) package, comprising:
an IC, comprising:
at least one die; and
a substrate having a surface, wherein the at least one die is attached to the surface of the substrate; and
a stiffener attached to the IC, comprising:
a planar portion having a first surface and a second surface; and
a plurality of adhesive portions disposed between the second surface of planar portion of the stiffener and the surface of the substrate.

9. The IC package of claim 8, wherein the plurality of adhesive portions are located at or near one or more corners of the second surface of the planar portion of the stiffener.

10. The IC package of claim 8, wherein the planar portion comprises a rectangular frame including at least one aperture.

11. The IC package of claim 8, wherein the planar portion comprises a perimeter frame attached at or near a perimeter of the surface of the substrate, the frame arranged apart from the at least one die on the surface of the substrate.

12. The IC package of claim 8, wherein the stiffener further comprises at least one removal tab.

13. The IC package of claim 12, wherein the at least one e oval tab comprises a handle.

14. The IC package of claim 12, wherein the at least one removal tab comprises a heat resistant tape.

15. The IC package of claim 8, wherein the adhesive is a debonding adhesive.

16.-20. (canceled)
